(19) United States
(12) Patent Application Publication
(10) Pub. No.: US 2026/0096285 A1
(43) Pub. Date: Apr. 2, 2026

(54) LIGHT-EMITTING DIODE AND DISPLAY APPARATUS AND ELECTRONIC DEVICE EACH INCLUDING THE LIGHT-EMITTING DIODE

(71) Applicants: Samsung Display Co., Ltd., Yongin-si (KR); University-Industry Cooperation Group of Kyung Hee University, Yongin-si (KR)

(72) Inventors: Yeonhwa Lee, Yongin-si (KR); Min Chul Suh, Seoul (KR); Joongu Lee, Yongin-si (KR); Sungsoon Im, Yongin-si (KR); Seung Ju Ok, Seoul (KR)

(21) Appl. No.: 19/339,107

(22) Filed: Sep. 24, 2025

(30) Foreign Application Priority Data
Sep. 30, 2024 (KR) 10-2024-0133250

(51) Int. Cl. H10K 50/814; H10K 50/17; H10K 50/82; H10K 102/00

(52) U.S. Cl. CPC H10K 50/814; H10K 50/171; H10K 50/82; H10K 2102/351

(57) ABSTRACT

A display apparatus includes a light-emitting diode, the light-emitting diode including a first electrode on a substrate, an emission layer on the first electrode, an electron injection layer on the emission layer, an auxiliary layer on the electron injection layer, and a second electrode on the auxiliary layer, wherein the electron injection layer includes a first material, the auxiliary layer includes a second material, and a surface energy of the second material is greater than a surface energy of the first material.

### CROSS-REFERENCE TO RELATED APPLICATION

This application claims priority to and the benefit of Korean Patent Application No. 10-2024-0133250, filed on Sep. 30, 2024, in the Korean Intellectual Property Office, the entire disclosure of which is incorporated herein by reference.

### BACKGROUND

### 1. Field

Embodiments of the present disclosure described herein are related to a light-emitting diode and a display apparatus including the light-emitting diode. For example, the embodiments of the present disclosure described herein are related to a light-emitting diode having high-temperature stability and a display apparatus including the light-emitting diode.

### 2. Description of the Related Art

Among display apparatuses, organic light-emitting display apparatuses are being used as next-generation devices due to their wide viewing angles, excellent or suitable contrast, and quick response speed.

Generally, organic light-emitting display apparatuses operate by thin-film transistors and organic light-emitting diodes (organic light-emitting diodes) formed on a substrate, wherein the light-emitting diodes self-emit light. Such organic light-emitting display apparatuses may be used as displays for smaller products such as mobile phones, or larger products such as televisions.

The light-emitting diode may have a structure wherein a first electrode (e.g., an anode) is arranged on a substrate, and a hole transport region, an emission layer, an electron transport region, and a second electrode (e.g., a cathode) are sequentially stacked on the first electrode. Holes injected from the first electrode move to the emission layer via the hole transport region, and electrons injected from the second electrode move to the emission layer via the electron transport region. Carriers such as holes and electrons recombine in the emission layer region to generate excitons. When the excitons change from an excited state to a ground state, light (e.g., an image) is generated.

The information disclosed in this Background section is intended to enhance understanding of the background of the disclosure and therefore it may contain information that does not constitute prior art.

### SUMMARY

Aspects according to one or more embodiments of the present disclosure are directed toward a light-emitting diode with (having) enhanced (e.g., excellent or suitable) high-temperature stability and a display apparatus including the light-emitting diode. However, the one or more embodiments are only examples, and the scope of the disclosure is not limited thereto.

Additional aspects will be set forth in part in the description which follows and, in part, will be apparent from the description, or may be learned by practice of the presented embodiments of the disclosure.

According to one or more embodiments, a light-emitting diode includes a first electrode, an emission layer on the first electrode, an electron injection layer on the emission layer, an auxiliary layer on the electron injection layer, and a second electrode on the auxiliary layer, wherein the electron injection layer includes a first material, the auxiliary layer includes a second material, and a surface energy of the second material is greater than a surface energy of the first material.

In one or more embodiments, the auxiliary layer may be in direct contact with the second electrode.

In one or more embodiments, the auxiliary layer may include a single metal material.

In one or more embodiments, the surface energy of the second material may be greater than 0.8 J/m².

In one or more embodiments, the second material may include aluminum (Al), iron (Zn), or copper (Cu).

In one or more embodiments, a thickness of the auxiliary layer may be less than a total thickness of the electron injection layer.

In one or more embodiments, a thickness of the auxiliary layer may be greater than 1 Å and less than or equal to 20 Å.

In one or more embodiments, the electron injection layer may include a first electron injection layer and a second electron injection layer on the first electron injection layer, and the first electron injection layer and the second electron injection layer may include different materials from each other.

In one or more embodiments, the second electrode may include a base metal and an additive metal, and a mass ratio of a content (e.g., amount) of the base metal included in the second electrode to a content (e.g., amount) of the additive metal included in the second electrode may be about 10:1 to about 50:1.

In one or more embodiments, the base metal may include silver (Ag), and the additive metal may include copper (Cu) or ytterbium (Yb).

According to one or more embodiments, a display apparatus includes a plurality of subpixels, wherein each of the plurality of subpixels includes a light-emitting diode and at least one thin-film transistor, wherein the light-emitting diode includes a first electrode on a substrate, an emission layer on the first electrode, an electron injection layer on the emission layer, an auxiliary layer on the electron injection layer, and a second electrode on the auxiliary layer, wherein the electron injection layer includes a first material, the auxiliary layer includes a second material, and a surface energy of the second material is greater than a surface energy of the first material.

In one or more embodiments, the auxiliary layer may be in direct contact with the second electrode.

In one or more embodiments, the auxiliary layer may include a single metal material.

In one or more embodiments, the surface energy of the second material may be greater than 0.8 J/m².

In one or more embodiments, the second material may include aluminum (Al), iron (Zn), or copper (Cu).

In one or more embodiments, a thickness of the auxiliary layer may be less than a total thickness of the electron injection layer.

In one or more embodiments, a thickness of the auxiliary layer may be greater than 1 Å and less than or equal to 20 Å.

In one or more embodiments, the electron injection layer may include a first electron injection layer and a second electron injection layer on the first electron injection layer, and the first electron injection layer and the second electron injection layer may include different materials from each other.

In one or more embodiments, the second electrode may include a base metal and an additive metal, and a mass ratio of a content (e.g., amount) of the base metal included in the second electrode to a content (e.g., amount) of the additive metal included in the second electrode may be about 10:1 to about 50:1.

In one or more embodiments, the base metal may include silver (Ag), and the additive metal may include copper (Cu) or ytterbium (Yb).

According to one or more embodiments, an electronic device includes the light display apparatus and/or the light-emitting diode.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to one or more embodiments;

FIG. 2A is an equivalent circuit diagram of a subpixel included in a display apparatus according to one or more embodiments;

FIG. 2B is an equivalent circuit diagram of a subpixel included in a display apparatus according to one or more embodiments;

FIG. 3 schematically shows a stack structure of a light-emitting diode according to one or more embodiments;

FIG. 4 schematically shows a stack structure of a light-emitting diode according to one or more embodiments;

FIG. 5 shows images of a surface of a second electrode of a light-emitting diode according to one or more embodiments, observed by using a scanning electron microscope;

FIG. 6A is a graph showing current densities with respect to voltages of Comparative Examples and Examples;

FIG. 6B is a graph showing luminance with respect to voltages of the Comparative Examples and Examples;

FIG. 7A is a graph showing current efficiencies with respect to luminance of Comparative Examples and Examples;

FIG. 7B is a graph showing power efficiencies with respect to luminance of Comparative Examples and Examples; and

FIG. 8 is a schematic cross-sectional view of a display apparatus including a light-emitting diode, according to one or more embodiments.

### DETAILED DESCRIPTION

Reference will now be made in more detail to one or more embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, one or more embodiments are merely described in more detail, by referring to the drawings, to explain aspects of the present description. As used herein, the term “and/or” includes any and all combinations of one or more of the associated listed items.

In the present specification, “including A or B”, “A and/or B”, etc., represents A or B, or A and B.

As used herein, the term “and/or” includes any and all combinations of one or more of the associated listed items. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

Because the disclosure may have diverse modified embodiments, example embodiments are illustrated in the drawings and are described in the detailed description. An effect and a characteristic of the disclosure, and a method of accomplishing these will be apparent if (e.g., when) referring to one or more embodiments described with reference to the drawings. The disclosure may, however, be embodied in many different forms and should not be construed as limited to one or more embodiments set forth herein.

One or more embodiments will be described in more detail herein with reference to the accompanying drawings. Those elements that may each independently be the same or are in correspondence are rendered the same reference numeral regardless of the drawing number, and redundant descriptions thereof are not provided.

In the specification, the terms “first” and “second” are not used in a limited sense and are used to distinguish one component from another component.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components. For example, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will be understood that if (e.g., when) a layer, region, or element is referred to as being formed “on” another layer, area, or element, it can be directly or indirectly formed on the other layer, region, or element. For example, for example, intervening layers, regions, or elements may be present.

In the drawings, for convenience of description, sizes of components may be exaggerated or reduced. For example, because sizes and thicknesses of elements in the drawings are arbitrarily illustrated for convenience of description, the following embodiments are not limited thereto.

When a certain embodiment may be implemented differently, a specific process order may be performed differently from the described order. For example, two consecutively described processes may be performed substantially at the same time or performed in an order opposite to the described order.

In this specification, the expression “A and/or B” may indicate A, B, or A and B. Also, the expression “at least one of A and B” may indicate A, B, or A and B.

In one or more embodiments hereinafter, it will be understood that if (e.g., when) an element, an area, or a layer is referred to as being connected to another element, area, or layer, it can be directly and/or indirectly connected to the other element, area, or layer. For example, in the specification, if (e.g., when) a layer, region, component, and/or the like is electrically connected to another layer, region, component, and/or the like, the layer, region, component, and/or the like may be directly electrically connected thereto and/or may be indirectly electrically connected thereto with an intervening layer, region, component, and/or the like therebetween.

In the following examples, the x-axis, the y-axis and the z-axis are not limited to three axes of the rectangular coordinate system, and may be interpreted in a broader sense. For example, the x-axis, the y-axis, and the z-axis may be normal (e.g., perpendicular) to one another, or may represent different directions that are not normal (e.g., not perpendicular) to one another.

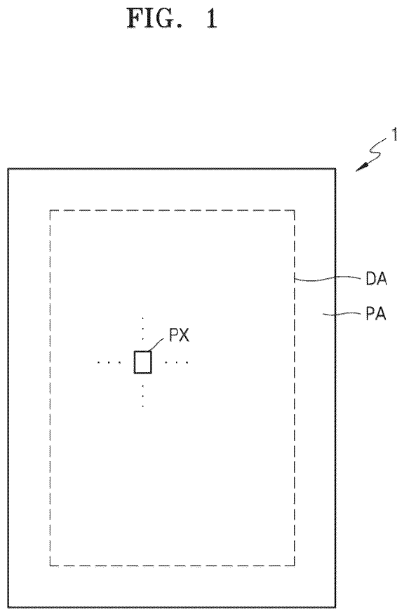

FIG. 1 is a schematic plan view of a display apparatus according to one or more embodiments.

Referring to FIG. 1, the display apparatus 1 may include a display area DA and a peripheral area PA outside the display area DA. In one or more embodiments, the peripheral area may be around the display area DA. The display apparatus 1 may provide an image through an array of subpixels PX arranged two-dimensionally in the display area DA.

Each subpixel PX of the display apparatus 1 may be configured to emit light of a set or predetermined color and provide an image by using the light emitted from the subpixels PX. For example, each subpixel PX may be configured to emit red, green, blue, or white light.

Each subpixel PX may be configured to emit light of a set or predetermined color by using a light-emitting diode, such as an organic light-emitting diode OLED. Each organic light-emitting diode OLED may be configured to emit, for example, red, green, blue or white light. Each organic light-emitting diode OLED may be connected to a subpixel circuit including a thin-film transistor and a capacitor. The number of thin-film transistors included in one subpixel circuit may vary from 1 to 7.

The peripheral area PA does not provide an image and may entirely be around (e.g., surround) the display area DA. The peripheral area PA may include a driver or a main power line to provide electrical signals or power to the subpixel circuits. The peripheral area PA may include a pad to which an electronic component or a printed circuit board may be electrically connected.

The display area DA may have a polygonal shape including a rectangle, as illustrated in FIG. 1. For example, the display area DA may have a rectangular shape wherein a horizontal length is greater than a vertical length, a rectangular shape wherein a horizontal length is less than a vertical length, or a square shape. In one or more embodiments, the display area DA may have one or more suitable shapes, such as an ellipse or a circle.

The display apparatus 1 may include a mobile phone, a television, a billboard, a tablet PC, a laptop, a smart watch or smart band worn on the wrist, and/or the like.

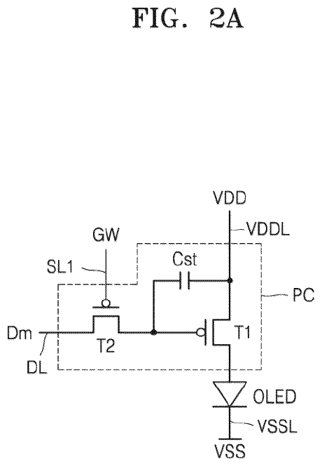

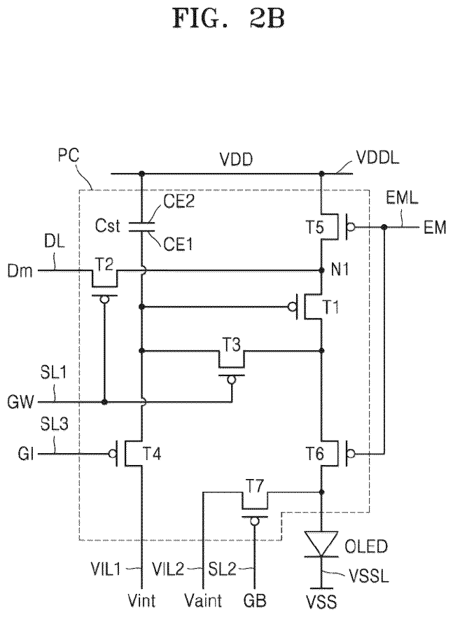

FIGS. 2A and 2B are equivalent circuit diagrams of a subpixel included in a display apparatus according to one or more embodiments.

Referring to FIG. 2A, the organic light-emitting diode OLED, which is a light-emitting diode corresponding to a subpixel PX, is electrically connected to a subpixel circuit PC, and the subpixel circuit PC may include a first transistor T1, a second transistor T2, and a storage capacitor Cst. The subpixel circuit PC may be electrically connected to a signal line and a voltage line. The signal line may include a gate line such as a first scan line SL1 and a data line DL and the voltage line may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may be configured to transmit data signals Dm input from the data line DL to the first transistor T1 according to the first scan signal GW input from the first scan line SL1.

The storage capacitor Cst may be electrically connected to the second transistor T2 and the first voltage line VDDL and may be configured to store a voltage corresponding to a difference between a voltage received from the second transistor T2 and a first power voltage VDD supplied from the first voltage line VDDL.

The first transistor T1 is a driving transistor that may control a driving current flowing through the organic light-emitting diode OLED. The first transistor T1 may be connected to the first voltage line VDDL and the storage capacitor Cst. The first transistor T1 may control the driving current flowing through the organic light-emitting diode OLED from the first voltage line VDDL in response to the voltage value stored in the storage capacitor Cst. The organic light-emitting diode OLED may be configured to emit light having a certain brightness according to the driving current. A first electrode of the organic light-emitting diode OLED may be electrically connected to the first transistor T1 and a second electrode of the organic light-emitting diode OLED may be electrically connected to a second voltage line VSSL configured to supply a second power supply voltage VSS.

FIG. 2A shows that the subpixel circuit PC includes two thin-film transistors and one storage capacitor, but in one or more embodiments, the pixel circuit PC may include three or more thin-film transistors.

Referring to FIG. 2B, the subpixel circuit PC may include the first transistor T1, the second transistor T2, a third transistor T3, a fourth transistor T4, a fifth transistor T5, a sixth transistor T6, a seventh transistor T7, and the storage capacitor Cst.

The subpixel circuit PC may be electrically connected to signal lines and voltage lines. The signal lines may include gate lines such as the first scan line SL1, a second scan line SL2, a third scan line SL3, a fourth scan line SL4, and an emission control line EML, and the data line DL. The voltage lines may include first and second initialization voltage lines VIL1 and VIL2 and the first voltage line VDDL.

The first voltage line VDDL may deliver the first power voltage VDD to the first transistor T1. The first initialization voltage line VIL1 may be configured to transmit a first initialization voltage Vint that initializes the first transistor T1 to the subpixel circuit PC. The second initialization voltage line VIL2 may be configured to transmit a second initialization voltage Vaint that initializes the first electrode of the organic light-emitting diode OLED to the subpixel circuit PC.

The first transistor T1 may be electrically connected to the first voltage line VDDL via the fifth transistor T5 and be electrically connected to the organic light-emitting diode OLED via the sixth transistor T6. The first transistor T1 acts as a driving transistor, receives a data signal Dm according to a switching operation of the second transistor T2, and supplies a driving current to the organic light-emitting diode OLED.

The second transistor T2 is a data write transistor and is electrically connected to the first scan line SL1 and the data line DL. The second transistor T2 is electrically connected to the first voltage line VDDL via the fifth transistor T5. The second transistor T2 is turned on in response to the first scan signal GW received through the first scan line SL1 and performs a switching operation to transmit the data signal Dm transmitted through the data line DL to a first node N1.

The third transistor T3 is electrically connected to the first scan line SL1 and is electrically connected to the organic light-emitting diode OLED via the sixth transistor T6. The third transistor T3 is be turned on in response to the first scan signal GW received through the first scan line SL1 and diode-connects the first transistor T1.

The fourth transistor T4 is a first initialization transistor and is electrically connected to the third scan line SL3 and the first initialization voltage line VIL1. The fourth transistor T4 is turned on according to a third scan signal GI received through the third scan line SL3 and transmits the first initialization voltage Vint from the first initialization voltage line VIL1 to a gate electrode of the first transistor T1 to initialize the voltage of the gate electrode of the first transistor T1. The third scan signal GI may correspond to a first scan signal of another subpixel circuit arranged in the previous row of the subpixel circuit PC.

The fifth transistor T5 may be an operation control transistor and the sixth transistor T6 may be an emission control transistor. The fifth transistor T5 and the sixth transistor T6 are electrically connected to the emission control line EML and are turned on concurrently (e.g., simultaneously) in response to an emission control signal EM received through the emission control line EML to form a current path such that a driving current may flow from the first voltage line VDDL toward the organic light-emitting diode OLED.

The seventh transistor T7 is a second initialization transistor and may be electrically connected to the second scan line SL2, the second initialization voltage line VIL2, and the sixth transistor T6. The seventh transistor T7 is turned on in response to the second scan signal GB received through the second scan line SL2 and transmits the second initialization voltage Vaint from the second initialization voltage line VIL2 to the first electrode of the organic light-emitting diode OLED to initialize the first electrode of the organic light-emitting diode OLED.

The storage capacitor Cst may include a lower electrode CE1 and an upper electrode CE2. The lower electrode CE1 is electrically connected to the gate electrode of the first transistor T1 and the upper electrode CE2 is electrically connected to the first voltage line VDDL. The storage capacitor Cst may maintain the voltage applied to the gate electrode of the first transistor T1 by storing and maintaining a voltage corresponding to a difference between voltages of both (e.g., opposite) ends of the first voltage line VDDL and the gate electrode of the first transistor T1. For example, the storage capacitor Cst may maintain the voltage applied to the gate electrode of the first transistor T1 by storing and maintaining a voltage corresponding to a difference between the voltages at the first voltage line VDDL and the gate electrode of the first transistor T1.

In FIG. 2B, all of the plurality of transistors T1 to T7 are illustrated as being P-type (kind), but the disclosure is not limited thereto. One or more suitable variations are possible. For example, at least one of the plurality of transistors T1 to T7 may be N-type (kind).

In one or more embodiments, at least one of the plurality of transistors T1 to T7 may include a semiconductor layer including oxide, and the others may include a semiconductor layer including silicon. For example, the third transistor T3 and the fourth transistor T4 may include an oxide semiconductor layer and the others may include a silicon semiconductor layer. However, the disclosure is not limited thereto. The plurality of transistors T1 to T7 may all include silicon semiconductor layers.

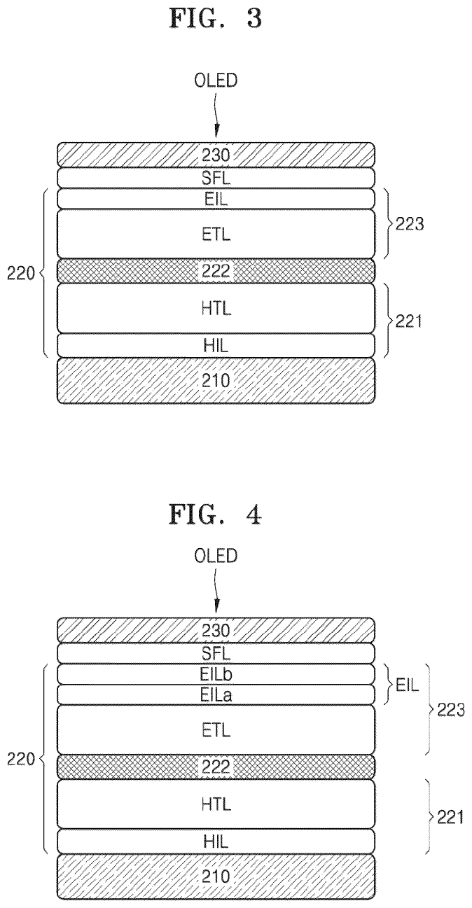

FIGS. 3 and 4 each schematically show a stack structure of a light-emitting diode according to one or more embodiments.

Referring to FIGS. 3 and 4, as a light-emitting diode, the organic light-emitting diode OLED may be included in each subpixel PX (refer to FIG. 1) of the display apparatus. An organic light-emitting diode OLED may be electrically connected to and driven by the subpixel circuit PC (refer to FIGS. 2A and 2B).

The organic light-emitting diode OLED may include a first electrode 210, a second electrode 230, and an intermediate layer 220 between the first electrode 210 and the second electrode 230. The first electrode 210 is patterned and provided for each organic light-emitting diode OLED, and the second electrode 230 may be provided in an integrated form in the plurality of organic light-emitting diodes OLED.

A first functional layer 221 may be arranged on the first layer 210. The first functional layer 221 may function as a hole transport region. The first functional layer 221 may include a hole injection layer, a hole transport layer, an emission auxiliary layer, an electron blocking layer, or any combination thereof.

The hole transport region may be provided as a single layer including a plurality of different materials, or may have a multi-layer structure wherein a hole injection layer/hole transport layer, a hole injection layer/hole transport layer/emission auxiliary layer, a hole injection layer/emission auxiliary layer, a hole transport layer/emission auxiliary layer, or a hole injection layer/hole transport layer/electron blocking layer are sequentially stacked on the first electrode 210, but the present disclosure is not limited thereto.

In one or more embodiments, the first functional layer 221 may include a hole injection layer HIL and a hole transport layer HTL. The hole injection layer HIL may be arranged adjacent to the first electrode 210, and a hole transport layer HTL may be arranged on the hole injection layer HIL.

The hole transport layer HTL may include a general hole transport material having high hole mobility. The hole transport layer HTL may include, but is not limited to, carbazole derivatives such as N-phenylcarbazole and polyvinylcarbazole, fluorine derivatives, triphenylamine derivatives such as N,N′-bis(3-methylphenyl)-N,N′-diphenyl-[1,1-biphenyl]-4,4′-diamine (TPD), 4,4′,4″-tris(Ncarbazolyl)triphenylamine (TCTA), N,N′-di(1-naphthyl)-N,N′-diphenylbenzidine (NPB), and/or 4,4′-Cyclohexylidene bis[N,N-bis(4-methylphenyl)benzenamine). The hole transport layer HTL may be a single layer including the above materials or may have a multi-layer structure including different materials from among the above materials. For example, the multi-layer structure may include a first layer and a second layer and the first layer and the second layer may each have a material different from each other and the each material may be from among (e.g., selected from among) the above materials.

The hole injection layer HIL may include a general hole injection material that facilitates hole injection. The hole injection layer HIL may be formed of, for example, at least one of HATCN and/or cupper phthalocyanine (CuPc), poly(3,4)-ethylenedioxythiophene (PEDOT), polyaniline (PANI), and/or N, N-dinaphthyl-N, N′-diphenylbenzidine (NPD), but embodiments are not limited thereto. The hole injection layer HIL may be a single layer including the above materials or may have a multi-layer structure including different materials from among the above materials. For example, the multi-layer structure may include a first layer and a second layer and the first layer and the second layer may each have a material different from each other and the each material may be from among (e.g., selected from among) the above materials

An emission layer 222 may be arranged on the first functional layer 221. The emission layer 222 may include an organic material, for example, a high molecular-weight or low molecular-weight organic material. The emission layer 222 may include a material that emits light of a set or predetermined color (red, green, or blue) and may include a fluorescent material or a phosphorescent material. The emission layer 222 may include a host and a dopant. For example, if (e.g., when) the emission layer 222 emits red light, the emission layer 222 may be formed using a red dopant in a set or predetermined host material. In one or more embodiments, if (e.g., when) the emission layer 222 emits green light, the emission layer 222 may be formed using a green dopant in a set or predetermined host material. In one or more embodiments, if (e.g., when) the emission layer 222 emits blue light, the emission layer 222 may be formed using a blue dopant in a set or predetermined host material.

A second functional layer 223 may be arranged on the emission layer 222. The second functional layer 223 may function as an electron transport region. The second functional layer 223 may include a buffer layer, a hole blocking layer, an electron control layer, an electron transport layer, an electron injection layer, or any combination thereof.

The electron transport region may be a single layer including a plurality of different materials, or may have a structure wherein an electron transport layer/electron injection layer, a hole blocking layer/electron transport layer/electron injection layer, an electron control layer/electron transport layer/electron injection layer, or a buffer layer/electron transport layer/electron injection layer are sequentially stacked on the emission layer 222, but the present disclosure is not limited thereto.

In one or more embodiments, the second functional layer 223 may include an electron transport layer ETL and an electron injection layer EIL. The electron transport layer ETL may be arranged on the emission layer 222 and the electron injection layer EIL may be arranged adjacent to the second electrode 230.

The electron transport layer ETL may include a general electron transport material that facilitates electron transportation. The electron transport layer ETL may include, for example, tris(8-hydroxyquinolinato)aluminum (Alq3), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq2), and/or 9,10-di(naphthalen-2-yl)anthracene (ADN), but the present disclosure is not limited thereto. The electron transport layer ETL may be a single layer including the above materials or may have a multi-layer structure including different materials from among the above materials. For example, the multi-layer structure may include a first layer and a second layer and the first layer and the second layer may each have a material different from each other and the each material may be from among (e.g., selected from among) the above materials.

The electron injection layer EIL may include a first material that facilitates electron injection. In one or more embodiments, the first material may include an alkali metal, an alkaline earth metal, a lanthanide metal, an alkali metal halide, an alkaline earth metal halide, a lanthanide metal halide, and/or a (e.g., any suitable) mixture thereof. In one or more embodiments, the first material may be lithium fluoride (LiF) or ytterbium (Yb).

The electron injection layer EIL may be a single layer including the above materials or may have a multi-layer structure including different materials from among the above materials. In one or more embodiments, as illustrated in FIG. 3, the electron injection layer EIL may be a single layer. In one or more embodiments, the electron injection layer EIL may include Yb. In one or more embodiments, as illustrated in FIG. 4, the electron injection layer EIL may have a multi-layer structure including a plurality of layers. The electron injection layer EIL may include a first electron injection layer EIL1 and a second electron injection layer EIL2 that are sequentially stacked. The first electron injection layer EIL1 and the second electron injection layer EIL2 may include different materials. For example, the first electron injection layer EIL1 and the second injection layer EIL2 may include materials different from each other. In one or more embodiments, the first electron injection layer EIL1 of the electron injection layer EIL may include LiF and the second electron injection layer EIL2 may include Yb. When the electron injection layer EIL has a multi-layer structure including the first electron injection layer EIL1 and the second electron injection layer EIL2, electron injection and device performance may be improved.

In one or more embodiments, the thickness of the first electron injection layer EIL1 and the thickness of the second electron injection layer EIL2 may each be about 3 Å to about 30 Å.

In one or more embodiments, the total thickness of the electron injection layer EIL may be from about 6 Å to about 60 Å. In one or more embodiments, the total thickness of the electron injection layer EIL may be from about 10 Å to about 30 Å, and the total thickness of the electron injection layer EIL may be from about 10 Å to about 26 Å.

The remaining layers excluding (e.g., not including) the emission layer 222, such as the hole injection layer HIL, the hole transport layer HTL, the electron transport layer ETL, and the electron injection layer EIL may each be formed integrally across the plurality of organic light-emitting diodes OLED.

Referring to FIGS. 3 and 4, the organic light-emitting diode OLED may include an auxiliary layer SFL arranged on the electron injection layer EIL. The auxiliary layer SFL may be arranged between the electron injection layer EIL of the second functional layer 223 and the second electrode 230. In one or more embodiments, the auxiliary layer SFL may be integrally formed across a plurality of organic light-emitting diodes OLED.

The auxiliary layer SFL may include a second material. The surface energy of the second material may be greater than the surface energy of the first material included in the electron injection layer EIL. In one or more embodiments, the surface energy of the second material may be more than 0.8 J/m². In one or more embodiments, the surface energy of the second material may be more than 0.8 J/m² but not more than 2 J/m². In one or more embodiments, the surface energy of the second material may be about 1.0 J/m² to about 1.8 J/m².

In the specification, the surface energy of a material may refer to the surface energy of the material at room temperature (approximately 25° C.).

In one or more embodiments, the second material may include a transition metal or a post-transition metal. In one or more embodiments, the second material may be zinc (Zn), aluminum (Al), or copper (Cu).

In one or more embodiments, the second material may be a single metal material. The auxiliary layer SFL may include a single metal material. The auxiliary layer SFL may include (e.g., may be composed of) a pure single metal element, excluding any unavoidable or undesirable impurities.

The thickness of the auxiliary layer SFL may be more than 1 Å but not more than 20 Å. In one or more embodiments, the thickness of the auxiliary layer SFL may be more than 1 Å but not more than 10 Å. The auxiliary layer SFL which is arranged between the electron injection layer EIL and the second electrode 230 and changes the characteristics of an interface, needs to be relatively thin within the above range. If the thickness of the auxiliary layer SFL is outside the above range, the auxiliary layer SFL may affect device characteristics other than interface characteristics in contact with the second electrode 230.

In one or more embodiments, the thickness of the auxiliary layer SFL may be less than the total thickness of the electron injection layer EIL. The total thickness of the electron injection layer EIL may be a sum of the thickness of the first electron injection layer EIL1 and the thickness of the second electron injection layer EIL2 if (e.g., when), for example, the electron injection layer EIL includes the first electron injection layer EIL1 and the second electron injection layer EIL2. For example, the total thickness of the electron injection layer EIL may be 16 Å, and the thickness of the auxiliary layer SFL may be 6 Å.

The second electrode 230 may be formed directly on the auxiliary layer SFL. The second electrode 230 may be in direct contact with the upper surface of the auxiliary layer SFL. An interface may be formed between the auxiliary layer SFL and the second electrode 230. The auxiliary layer SFL may be a mediating layer for evenly forming a film on the second electrode 230 without coagulation.

The second electrode 230 may include a third material having a relatively high surface energy. The second electrode 230 may include a base metal and an additive metal. The base metal and the additive metal may be different materials. In this case, the second electrode 230 including the base metal and the additive metal may refer to a material wherein the base metal and the additive metal are alloyed, or a material wherein elements of the base metal and the additive metal exist concurrently (e.g., simultaneously). The second electrode 230 may be formed by depositing an alloy of a base metal and an additive metal or by co-depositing a base metal and an additive metal.

In one or more embodiments, the base metal may include at least one material selected from among Ag, Al, Cu, and Mg. In one or more embodiments, the additive metal may include at least one metal having an electrical conductivity of 1×10⁷ S/m or greater. In one or more embodiments, the additive metal may include at least one selected from among Ag, Mg, Ca, Li, Au, Al, Yb, Cu, and Sm. In one or more embodiments, the additive metal may include at least one metal having a work function of 3 eV or less. In this case, the base metal and the additive metal may be selected as different metal materials.

In one or more embodiments, the additive metal of the second electrode 230 may be the same as the second material of the auxiliary layer SFL. In one or more embodiments, the second electrode 230 and the auxiliary layer SFL may include Cu.

In one or more embodiments, the bonding energy of the second electrode 230 may be 1 eV or greater. In one or more embodiments, the bonding energy of the second electrode 230 may be about 1 eV or more and about 4 eV or less. Herein, the bonding energy of the second electrode 230 may refer to the binding energy between metal elements included in the second electrode 230. If the bonding energy of the second electrode 230 satisfies the above ranges, a stable second electrode 230 without phase separation may be formed. Accordingly, the device characteristics may be improved. In one or more embodiments, the second electrode 230 may include Ag and Cu or may include Ag and Yb.

In one or more embodiments, in the second electrode 230, a mass ratio of the content (e.g., amount) of the base metal to the content (e.g., amount) of the additive metal may be about 10:1 to about 50:1. When the mass ratio of the content (e.g., amount) of the base metal in the second electrode 230 to the content (e.g., amount) of the additive metal in the second electrode 230 is less than about 10:1, the efficiency of the light-emitting element may decrease. In contrast, if (e.g., when) the mass ratio of the content (e.g., amount) of the base metal in the second electrode 230 to the content (e.g., amount) of the additive metal in the second electrode 230 exceeds about 50:1, some metals used as the base metal, such as Ag, may coagulate, which may reduce reliability.

For example, in one or more embodiments, about 90.9 mass % to about 98 mass % of base metal may be included in the second electrode 230 and about 2.0 mass % to about 19.1 mass % of additive metal may be included in the second electrode 230. In one or more embodiments, the base metal of the second electrode 230 may be Ag and the additive metal may be Cu or Yb. The second electrode 230 may be an Ag-rich layer having a high Ag content (e.g., amount).

In one or more embodiments, the second electrode 230 may be a transmissive electrode, a semi-transmissive electrode, or a reflective electrode. In one or more embodiments, the second electrode 230 may have a single-layer structure including a layer or a multi-layer structure including a plurality of layers.

In one or more embodiments, the surface energy of the second material of the auxiliary layer SFL may be substantially equal (e.g., equal) to or greater than the surface energy of the third material of the second electrode 230.

In one or more embodiments, the second material and the third material may satisfy the Equation (1).

$$X 1 - X 2 < 0.15 \qquad ( 1 )$$

In the above Equation (1), X1 refers to the surface energy of the third material at 25° C. and X2 refers to the surface energy of the second material.

For example, X1-X2 may be less than 0.05. In one or more embodiments, X1-X2 may be less than 0 (i.e., negative). When the above ranges are satisfied, an interaction between the third materials of the second electrode 230 on the second materials of the auxiliary layer SFL is increased, thereby allowing deposition of the second electrode 230 on the auxiliary layer SFL without coagulation.

In one or more embodiments, X2 can be more than 0.8 J/m². In one or more embodiments, X2 may be more than 0.8 J/m² but not more than 2 J/m². In one or more embodiments, X2 may be about 1.0 J/m² to about 1.8 J/m². In one or more embodiments, X1 may be more than 1.2 J/m² but not more than 2.0 J/m². In one or more embodiments, X1 may be more than 1.2 J/m² but not more than 1.5 J/m².

In one or more embodiments, the thickness of the second electrode 230 may be from about 90 Å to about 1,000 Å. In one or more embodiments, the thickness of the second electrode 230 may be 200 Å.

In a comparative example, if (e.g., when) the second electrode 230 is deposited directly on the electron injection layer EIL, the surface energy of the first material of the electron injection layer EIL is less than the surface energy of the third material of the second electrode 230 and the difference between the two surface energies is great, thereby causing coagulation if (e.g., when) the second electrode 230 is deposited on the electron injection layer EIL. The surface of the second electrode 230 may not be flat. In this case, pixel shrinkage phenomenon may occur at high temperatures. The high-temperature stability of the organic light-emitting diode OLED may be reduced.

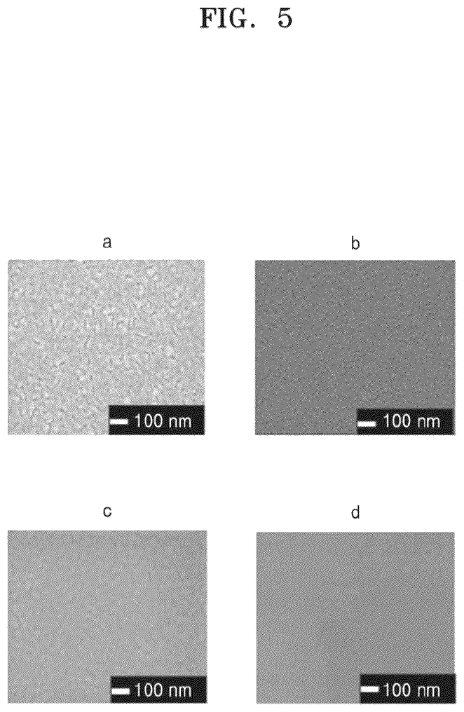

The organic light-emitting diode OLED according to one or more embodiments may further include the support layer SFL arranged between the electron injection layer EIL and the second electrode 230. Because the second material of the auxiliary layer SFL has a surface energy that is substantially similar or similar to the surface energy of the third material of the second electrode 230 or has a surface energy that is greater than the surface energy of the third material of the second electrode 230, the interaction between the auxiliary layer SFL and the second electrode 230 increases, such that the second electrode 230 may be deposited on the auxiliary layer SFL in a flat manner without coagulation. As described in more detail with reference to FIG. 5, the surface of the second electrode 230 may be smooth. Therefore, pixel shrinkage phenomenon may not occur even at high temperatures, and the high-temperature stability of the light-emitting diode may be improved. For example, the present disclosure describes an organic light-emitting diode (OLED) that includes an auxiliary layer (SFL) arranged between the electron injection layer (EIL) and the second electrode. This auxiliary layer is composed of a second material with higher surface energy than the first material in the EIL, which helps to prevent or reduce coagulation and ensures a smooth deposition of the second electrode. The auxiliary layer's thickness is carefully controlled to enhance device performance without affecting other characteristics. The second electrode is made of a base metal and an additive metal, with specific ratios to enhance stability and performance. The disclosure details the materials and properties of these layers, emphasizing the improved high-temperature stability and overall efficiency of the OLED due to the presence of the auxiliary layer.

FIG. 5 shows images of the surface of the second electrode of the light-emitting diode according to one or more embodiments, observed by using a scanning electron microscope.

In Examples (a) to (d), an electron injection layer was formed, followed by an auxiliary layer on the electron injection layer, and then a second electrode on the auxiliary layer. The electron injection layer of Example (a) was formed of an Yb layer, the auxiliary layer was formed of an Al layer, and the second electrode was formed of an Ag layer. The electron injection layer of Example (b) includes an Yb layer, the auxiliary layer includes an Al layer, and the second electrode includes a layer (Ag:Mg) including Ag and Mg. The electron injection layer of Example (c) includes an Yb layer, the auxiliary layer includes a Cu layer, and the second electrode includes a layer (Ag:Cu) including Ag and Cu. The electron injection layer of Example (d) has a multi-layer structure wherein the first electron injection layer and the second electron injection layer are sequentially stacked, wherein the first electron injection layer includes a lithium fluoride (LiF) layer, the second electron injection layer includes a ytterbium (Yb) layer, the auxiliary layer includes a copper (Cu) layer, and the second electrode includes a layer (Ag:Cu) including silver (Ag) and copper (Cu). The surface of the second electrode of Examples (a) to (d) was observed using a scanning electron microscope (SEM), and the results are shown in FIG. 5. Drawings (a) to (d) of FIG. 5 show result images of Examples (a) to (d), respectively.

Referring to FIG. 5, it was confirmed that the second electrodes of Examples (a) to (d) have relatively clean surfaces. For example, in the case of Examples (a) and (b), the surface energy (1.143 J/m²) of aluminum (Al) included in the auxiliary layer is similar to the surface energy (1.246 J/m²) of silver (Ag) included in the second electrode, and the second electrode formed on the auxiliary layer does not show any aggregation, but slight wrinkles are observed on the surface. In addition, in the case of Examples (c) and (d), the surface energy (1.79 J/m²) of copper (Cu) included in the auxiliary layer is greater than the surface energy of silver (Ag) included in the second electrode, so it can be seen that the grain boundary size of the second electrode formed on the auxiliary layer is reduced and the overall surface of the second electrode is clean.

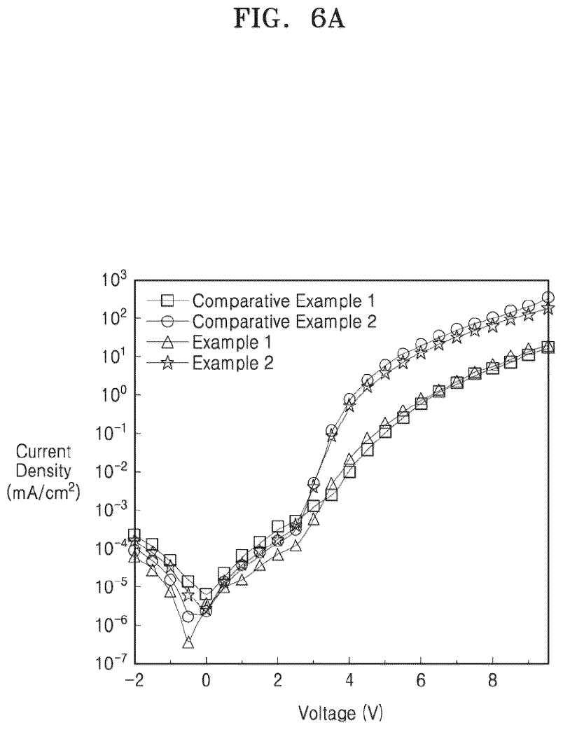

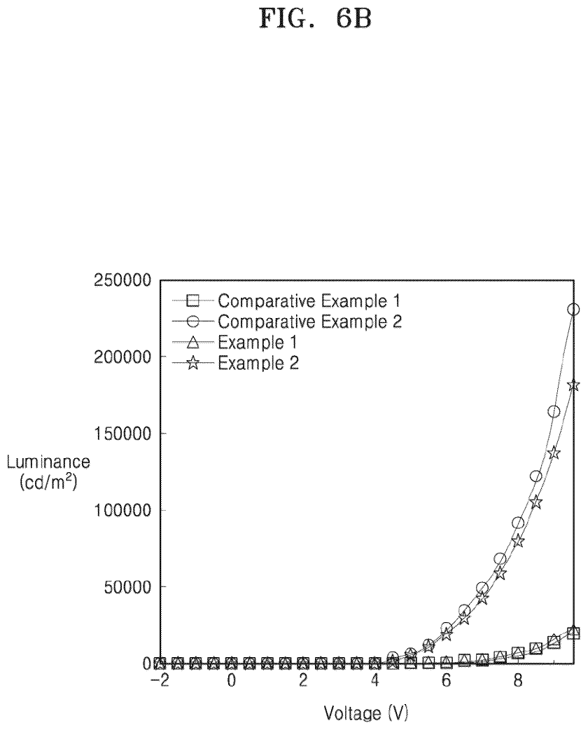

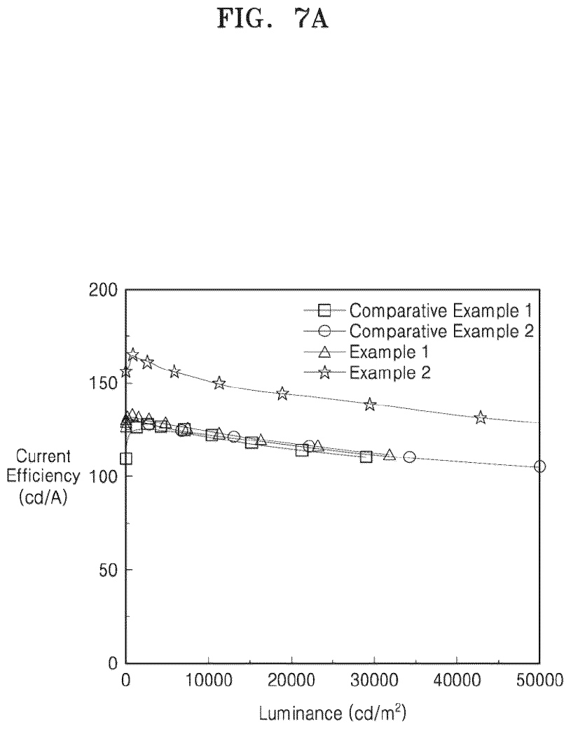

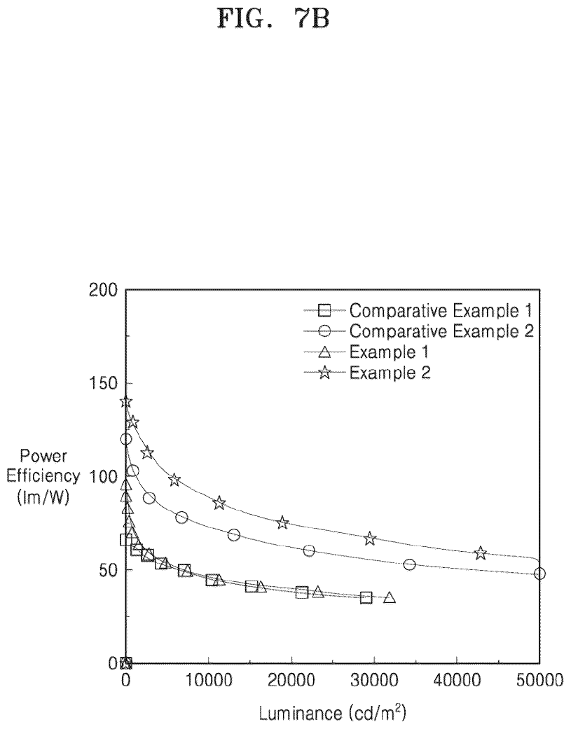

FIG. 6A is a graph showing the current density of Comparative Examples and Examples with respect to the voltage of Comparative Examples and Examples, and FIG. 6B is a graph showing the luminance of Comparative Examples and Examples with respect to the voltage of Comparative Examples and Examples. In addition, FIG. 7A is a graph showing current efficiency (CE) with respect to the luminance of the Comparative Examples and Examples, and FIG. 7B is a graph showing power efficiency (PE) with respect to the luminance of Comparative Examples and Examples.

In Comparative Examples 1 and 2, an electron injection layer was formed, followed by a second electrode on the electron injection layer. In Examples 1 and 2, an electron injection layer was formed, followed by an auxiliary layer on the electron injection layer, and then a second electrode on the auxiliary layer. The second electrode was formed of a layer (Ag:Cu) including Ag and Cu. The electron injection layer of Comparative Example 1 was formed of an Yb layer. The electron injection layer of Comparative Example 2 has a multi-layer structure including the first electron injection layer and the second electron injection layer are sequentially stacked, wherein the first electron injection layer includes a LiF layer, and the second electron injection layer includes a Yb layer. The electron injection layer of Example 1 was formed of an Yb layer and the auxiliary layer was formed of a Cu layer. The electron injection layer of Example 2 has a multi-layer structure including the first electron injection layer and the second electron injection layer are sequentially stacked, wherein the first electron injection layer includes a LiF layer, and the second electron injection layer includes a Yb layer. In Comparative Example 1, the thickness of the electron injection layer is 13 Å, in Comparative Example 2, the thickness of the electron injection layer is 16 Å, wherein the thicknesses of the first electron injection layer and the second electron injection layer of the electron injection layer are respectively 3 Å and 13 Å, in Example 1, the thicknesses of the electron injection layer and the auxiliary layer are respectively 13 Å and 6 Å, and, in Example 2, the thicknesses of the electron injection layer and the auxiliary layer are respectively 16 Å and 6 Å, wherein the thicknesses of the first electron injection layer, the second electron injection layer, and the auxiliary layer are respectively 3 Å, 13 Å, and 6 Å.

The current density and luminance with respect to the voltage, and the current efficiency and power efficiency with respect to the luminance of Comparative Example 1, Comparative Example 2, Example 1, and Example 2 were measured. The results are shown in Table 1 and FIGS. 6A to 7B.

TABLE 1

| | | J (mA/cm²) | C.E (cd/A) | P.E (lm/W) |
|---|---|---|---|---|
| | Vₒₙ (V) | (@ 6 V) | (@ MAX) | (@MAX) |
| Comparative | 4 | 0.6 | 128 | 86 |
| Example 1 | | | | |
| Comparative | 2.5 | 19 | 133 | 120 |
| Example 2 | | | | |
| Example 1 | 2.5 | 0.42 | 147 | 82 |
| Example 2 | 2.5 | 13 | 165 | 130 |

Referring to Table 1 and FIGS. 6A to 7B, compared to Comparative Example 1, Example 1 shows reduced Von voltage and improved current efficiency with respect to luminance. In addition, compared to Comparative Example 2, Example 2 shows reduced Von voltage and improved current efficiency with respect to luminance. Compared to Comparative Example 1, Comparative Example 2 shows reduced Von voltage and overall improved current efficiency and voltage efficiency with respect to the current density and luminance in substantially the same voltage. Compared to Example 1, Example 2 shows overall improved current efficiency and voltage efficiency with respect to the current density and luminance in substantially the same voltage.

For example, the electron injection and device characteristics of Examples 1 and 2 including the auxiliary layer SFL are shown to be improved. In addition, Example 2, which has an electron injection layer having a multi-layer structure, showed improved electrical characteristics compared to Example 1 due to an increase in the current density at the same voltage (e.g., 6 V).

Accordingly, the organic light-emitting diode according to one or more embodiments shows improved device performance by including the auxiliary layer SFL between the electron injection layer EIL and the second electrode 230. In addition, the organic light-emitting diode showed further improved electron injection and device characteristics by including the electron injection layer EIL having a multi-layer structure and the auxiliary layer SFL between the electron injection layer EIL and the second electrode 230. For example, the present disclosure describes an organic light-emitting diode (OLED) that includes an auxiliary layer (SFL) arranged between the electron injection layer (EIL) and the second electrode. This auxiliary layer, made of a second material with higher surface energy than the first material in the EIL, helps prevent coagulation and ensures a smooth deposition of the second electrode. The auxiliary layer's thickness is carefully controlled to enhance device performance without affecting other characteristics. Experimental results, including SEM images and performance graphs, demonstrate that the OLEDs with the auxiliary layer exhibit cleaner surfaces and improved electrical characteristics compared to those without the auxiliary layer. Specifically, the OLEDs with the auxiliary layer show reduced Von voltage, improved current efficiency, and better overall device performance. The inclusion of a multi-layer structure in the electron injection layer further enhances these improvements, leading to increased current density and stability at high temperatures.

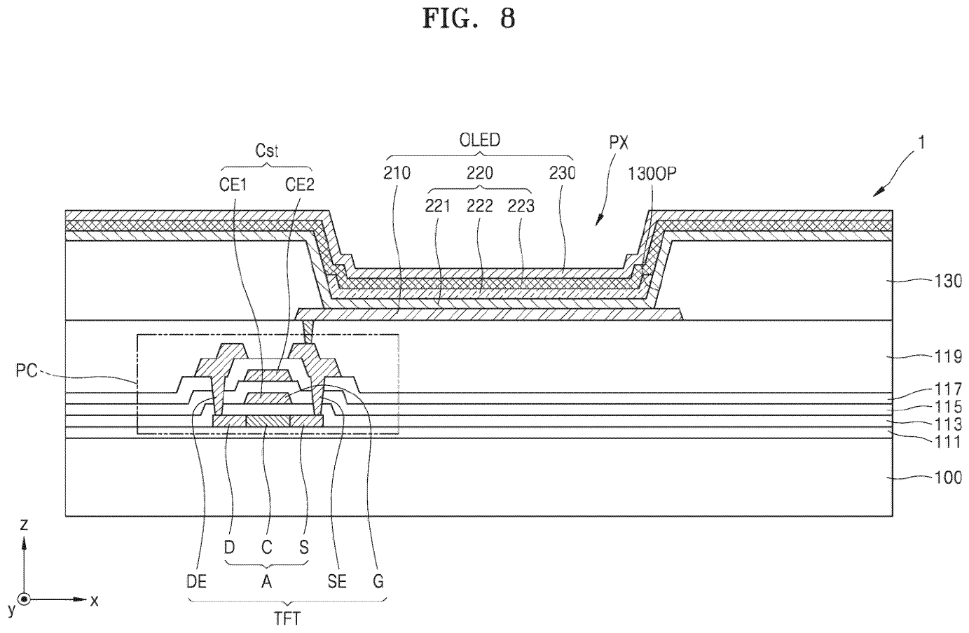

FIG. 8 is a schematic cross-sectional view of a display apparatus including a light-emitting diode, according to one or more embodiments.

Referring to FIG. 8, the display apparatus 1 may include a light-emitting diode that emits light. The display apparatus 1 includes the subpixel PX, and the subpixel PX may be configured to emit light of a set or predetermined color by using the organic light-emitting diode OLED.

An organic light-emitting diode OLED may be electrically connected to the subpixel circuit PC between the substrate 100 and the organic light-emitting diode OLED along a direction normal (e.g., perpendicular) to the substrate 100 (e.g., the z direction).

The substrate 100 may include glass materials or polymer resins. In one or more embodiments, the substrate 100 may have an alternating stack structure of a base layer including a polymer resin and a barrier layer including an inorganic insulating material such as silicon oxide or silicon nitride. The polymer resin may include polyethersulfone, polyarylate, polyether imide, polyethylene naphthalate, polyethylene terephthalate, polyphenylene sulfide, polyimide, polycarbonate, cellulose triacetate, cellulose acetate propionate, and/or the like.

Before the subpixel circuit PC is formed, a buffer layer 111 may be formed on the substrate 100 to prevent or reduce impurities from penetrating into the subpixel circuit PC. The buffer layer 111 may include an inorganic insulating material, such as silicon nitride, silicon oxynitride, and/or silicon oxide, and may have a single-layer or multi-layer structure including such a material.

The subpixel circuit PC may include a thin-film transistor TFT and the storage capacitor Cst. The thin-film transistor TFT may include a semiconductor layer A, a gate electrode G, a source electrode SE, and a drain electrode DE.

The semiconductor layer A may be arranged on the buffer layer 111. The semiconductor layer A may include polysilicon. In one or more embodiments, the semiconductor layer A may include amorphous silicon, an oxide semiconductor, or an organic semiconductor. In one or more embodiments, the semiconductor layer A may include a channel region C and a source region S and a drain region D respectively arranged on either side of the channel region C.

The gate electrode G may overlap the channel region C of the semiconductor layer A. The gate electrode G may include a low-resistance metal material.

The first inorganic insulating layer 113 may be arranged between the semiconductor layer A and the gate electrode G. The first inorganic insulating layer 113 may include an inorganic insulating material such as silicon oxide, silicon nitride, silicon oxynitride, aluminum oxide, titanium oxide, tantalum oxide, hafnium oxide, or zinc oxide.

The second inorganic insulating layer 115 may cover the gate electrode G. The second inorganic insulating layer 115 may, similarly to the first inorganic insulating layer 113, include an inorganic insulating material such as silicon oxide, silicon nitride, silicon oxynitride, aluminum oxide, titanium oxide, tantalum oxide, hafnium oxide, and/or zinc oxide.

An upper electrode CE2 of the storage capacitor Cst may be arranged on the second inorganic insulating layer 115. In one or more embodiments, the upper electrode CE2 may overlap the gate electrode G. In this case, the gate electrode G and the upper electrode CE2 overlapping each other with the second inorganic insulating layer 115 therebetween may form the storage capacitor Cst. For example, the gate electrode G may function as a lower electrode CE1 of the storage capacitor Cst. As described above, the storage capacitor Cst may overlap the first thin-film transistor TFT. In one or more embodiments, the storage capacitor Cst may not overlap the thin-film transistor TFT.

The third inorganic insulating layer 117 may cover the upper electrode CE2. The third inorganic insulating layer 117 may include silicon oxide, silicon nitride, silicon oxynitride, aluminum oxide, titanium oxide, tantalum oxide, hafnium oxide, and/or zinc oxide. The third inorganic insulating layer 117 may be a single layer or multiple layers including the above inorganic insulating material.

The source electrode SE and the drain electrode DE may each be arranged on the third inorganic insulating layer 117. A least one of the source electrode SE and the drain electrode DE may include a material having good or suitable conductivity. At least one of the source electrode SE and the drain electrode DE may include a conductive material including Mo, Al, Cu, Ti, and/or the like, and have a single-layer structure or a multi-layer structure including the above materials. In one or more embodiments, at least one of the source electrode SE and the drain electrode DE may have a multi-layer structure of Ti/Al/Ti.

An organic insulating layer 119 may be arranged on the third inorganic insulating layer 117. The organic insulating layer 119 may be arranged on the source electrode SE and the drain electrode DE. The organic insulating layer 119 may include an organic material. The organic insulating layer 119 may include an organic insulating material, such as a general-purpose polymer, such as polymethylmethacrylate (PMMA) and/or polystyrene (PS), polymer derivatives having a phenol-based group, acryl-based polymers, imide-based polymers, aryl ether-based polymers, amide-based polymers, fluorine-based polymers, p-xylene-based polymers, vinyl alcohol-based polymers, and/or a blend thereof. For example, this layer 119 may be made of an organic insulating material, which may include one or more of various polymers such as polymethylmethacrylate (PMMA), polystyrene (PS), and/or other polymer derivatives. The one or more materials provide effective insulation.

A light-emitting diode, such as the organic light-emitting diode OLED, may be arranged on the organic insulating layer 119. The organic light-emitting diode OLED may be configured to emit, for example, red, green, or blue light, or red, green, blue, or white light. The organic light-emitting diode OLED may include the first electrode 210, the intermediate layer 220, and the second electrode 230. The intermediate layer 220 of the organic light-emitting diode OLED may further include the first functional layer 221 between the first electrode 210 and the emission layer 222 and the second functional layer 223 between the emission layer 222 and the second electrode 230.

The first electrode 210 may be arranged on the organic insulating layer 119. The first electrode 210 may be electrically connected to a thin-film transistor TFT. For example, the first electrode 210 may be connected to the thin-film transistor TFT through a contact hole of the organic insulating layer 119. The first electrode 210 may include a conductive oxide, such as indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, the first electrode 210 may include a reflective layer including Ag, Mg, Al, Pt, Pd, Au, Ni, Nd, Ir, Cr, or a compound thereof. In one or more embodiments, the first electrode 210 may further include a layer including ITO, IZO, ZnO, and/or In₂O₃ above/below the reflective layer described above.

A bank layer 130 including an opening 130OP exposing a center portion of the first electrode 210 may be arranged on the first electrode 210. The bank layer 130 may include an organic insulating material and/or an inorganic insulating material. The opening 130OP of the bank layer 130 may define an emission area of light emitted from the organic light-emitting diode OLED.

The emission layer 222 of the intermediate layer 220 may be arranged in the opening 130OP of the bank layer 130. The first functional layer 221 may be arranged below the emission layer 222 and the second functional layer 223 may be arranged above the emission layer 222. The second electrode 230 may be arranged on the intermediate layer 220. The first functional layer 221, the second functional layer 223, and the second electrode 230 may cover the entire substrate 100.

The organic light-emitting diode OLED may be applied to the structure described in more detail with reference to FIGS. 3 and 4. The second functional layer 223 may include the electron injection layer EIL. The organic light-emitting diode OLED according to one or more embodiments may include the support layer SFL arranged between the electron injection layer EIL and the second electrode 230. Because the organic light-emitting diode OLED includes the auxiliary layer SFL, the second electrode 230 may be flat without coagulation. Because the surface of the second electrode 230 is smooth, the high-temperature stability of the organic light-emitting diode OLED and the device characteristics may be improved.

A capping layer may be arranged on the second electrode 230. For example, the capping layer may be a single layer or multiple layers including a material selected from among organic materials, inorganic materials, and mixtures thereof. In one or more embodiments, the capping layer may enhance the external luminescence efficiency by the constructive interference principle. In one or more embodiments, the capping layer may include a material having a refractive index of 1.6 or greater. In one or more embodiments, a LiF layer may be arranged on the capping layer.

In one or more embodiments, an encapsulation layer may be arranged on the organic light-emitting diode OLED. The encapsulation layer may include at least one inorganic encapsulation layer and at least one organic encapsulation layer each covering the organic light-emitting diode OLED. In one or more embodiments, the at least one inorganic encapsulation layer and the at least one organic encapsulation layer may be alternately stacked. The at least one of inorganic encapsulating layer may include at least one inorganic material selected from among aluminum oxide, titanium oxide, tantalum oxide, zinc oxide, silicon oxide, silicon nitride, and silicon oxynitride. The at least one organic encapsulation layer may include a polymer-based material. Examples of the polymer-based material may include an acrylic resin, an epoxy resin, polyimide, and polyethylene. In one or more embodiments, the organic encapsulation layer 320 may include acrylate.

The light-emitting diode, according to one or more embodiments described above, may have excellent or suitable high-temperature stability by including the auxiliary layer between the electron injection layer and the second electrode. The display apparatus including the light-emitting diode as above may have improved reliability. However, the scope of the disclosure is not limited by these effects.

According to one or more embodiments, an electronic device includes the light display apparatus and/or the light-emitting diode.

The display device, the electronic apparatus, the electronic equipment or device, a manufacturing device for the display device, the electronic apparatus, the electronic equipment or device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

The utilization of “may” when describing embodiments of the present disclosure refers to “one or more embodiments of the present disclosure.”

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A light-emitting diode comprising:
a first electrode;
an emission layer on the first electrode;
an electron injection layer on the emission layer;
an auxiliary layer on the electron injection layer; and
a second electrode on the auxiliary layer,
wherein:
the electron injection layer comprises a first material,
the auxiliary layer comprises a second material, and
a surface energy of the second material is greater than a surface energy of the first material.

2. The light-emitting diode of claim 1, wherein the auxiliary layer is in direct contact with the second electrode.

3. The light-emitting diode of claim 1, wherein the auxiliary layer comprises a single metal material.

4. The light-emitting diode of claim 1, wherein the surface energy of the second material is greater than 0.8 J/m².

5. The light-emitting diode of claim 1, wherein the second material comprises at least one of aluminum (Al), iron (Zn), or copper (Cu).

6. The light-emitting diode of claim 1, wherein a thickness of the auxiliary layer is less than a total thickness of the electron injection layer.

7. The light-emitting diode of claim 1, wherein a thickness of the auxiliary layer is greater than 1 Å and less than or equal to 20 Å.

8. The light-emitting diode of claim 1, wherein:
the electron injection layer comprises a first electron injection layer and a second electron injection layer on the first electron injection layer, and
the first electron injection layer and the second electron injection layer comprise different materials from each other.

9. The light-emitting diode of claim 1, wherein:
the second electrode comprises a base metal and an additive metal, and
a mass ratio of a content of the base metal in the second electrode to a content of the additive metal in the second electrode is about 10:1 to about 50:1.

10. The light-emitting diode of claim 9, wherein:
the base metal comprises silver (Ag), and
the additive metal comprises at least one of copper (Cu) or ytterbium (Yb).

11. A display apparatus comprising:
a plurality of subpixels,
wherein each of the plurality of subpixels comprises a light-emitting diode and at least one thin-film transistor,
wherein the light-emitting diode comprises:
a first electrode on a substrate;
an emission layer on the first electrode;
an electron injection layer on the emission layer;
an auxiliary layer on the electron injection layer; and
a second electrode on the auxiliary layer, and
wherein:
the electron injection layer comprises a first material,
the auxiliary layer comprises a second material, and
a surface energy of the second material is greater than a surface energy of the first material.

12. The display apparatus of claim 11, wherein the auxiliary layer is in direct contact with the second electrode.

13. The display apparatus of claim 11, wherein the auxiliary layer comprises a single metal material.

14. The display apparatus of claim 11, wherein the surface energy of the second material is greater than 0.8 J/m².

15. The display apparatus of claim 11, wherein the second material comprises at least one of aluminum (Al), iron (Zn), or copper (Cu).

16. The display apparatus of claim 11, wherein a thickness of the auxiliary layer is less than a total thickness of the electron injection layer.

17. The display apparatus of claim 11, wherein a thickness of the auxiliary layer is greater than 1 Å and less than or equal to 20 Å.

18. The display apparatus of claim 11, wherein:
the electron injection layer comprises a first electron injection layer and a second electron injection layer on the first electron injection layer, and
the first electron injection layer and the second electron injection layer comprise different materials from each other.

19. The display apparatus of claim 11, wherein:
the second electrode comprises a base metal and an additive metal, and
a mass ratio of a content of the base metal in the second electrode to a content of the additive metal in the second electrode is about 10:1 to about 50:1.

20. An electronic device comprising:
a display apparatus comprising:
a plurality of subpixels,
wherein each of the plurality of subpixels comprises a light-emitting diode and at least one thin-film transistor,
wherein the light-emitting diode comprises:
a first electrode on a substrate;
an emission layer on the first electrode;
an electron injection layer on the emission layer;
an auxiliary layer on the electron injection layer; and
a second electrode on the auxiliary layer, and
wherein:
the electron injection layer comprises a first material,
the auxiliary layer comprises a second material, and
a surface energy of the second material is greater than a surface energy of the first material.
